(19) United States
(12) Patent Application Publication
(10) Pub. No.: US 2025/0391647 A1
(43) Pub. Date: Dec. 25, 2025

(54) System and Method for Atomic Layer Etching with Autonomous Process Recipe Generation

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/750,550

(22) Filed: Jun. 21, 2024

(51) Int. Cl. H01J 37/32; G05B 19/4155; H01L 21/3065; H01L 21/311; H01L 21/3213

(52) U.S. Cl. CPC H01J 37/32926; G05B 19/4155; H01J 37/32082; H01J 37/3244; G05B 2219/45212; H01J 2237/334; H01L 21/3065; H01L 21/31116; H01L 21/32136

(57) ABSTRACT

Disclosed herein is an advanced atomic layer etching (ALE) process system, augmented with a system digital twin capable of autonomously generating process recipe parameters and subsystem control parameters. This digital twin-driven system enables precise simulations, fostering efficient and adaptable semiconductor processing. In some embodiments, the process recipe is generated by a system controller through an optimization procedure based on a predefined cost function utilizing the system digital twin. A novel method is proposed for providing initial parameter estimates, leveraging numerous simulated cases accumulated over time in the background. This inventive concept can be readily applied to any type of etching and deposition process systems employing a vacuum plasma chamber.

### FIELD OF THE INVENTION

The present invention pertains to the field of semiconductor manufacturing, specifically to the development and optimization of atomic layer etching (ALE) processes. It relates to systems and methods that enhance the precision and efficiency of etching processes by integrating various subsystem digital twins into a comprehensive system digital twin. This integration enables the autonomous generation and adjustment of process recipe parameters and subsystem control parameters.

### BACKGROUND

ALE is crucial in the fabrication of semiconductor devices, allowing precise control to produce features at the nanometer scale. Traditionally, ALE process systems have relied on pre-developed process recipes created by experienced process engineers, which consume significant resources. Engineers must manually conduct design of experiments (DOE) to identify optimized processing conditions, using valuable substrates in the process. Manual adjustments of etching parameters, such as gas flow rates, RF power levels, and chuck temperature, have been standard practice during recipe development.

However, with the increasing complexity of semiconductor devices and the need for higher precision and repeatability, manual adjustments and static recipes are no longer sufficient to meet the industry's advancing standards. There is a growing need for improved ALE process systems that can adapt to a variety of etching scenarios without extensive human intervention.

The development of digital twins-virtual representations of real-world systems-provides an opportunity to significantly improve ALE processes. A digital twin allows the simulation of the real-world etching process in a virtual environment, enabling the prediction and optimization of etching outcomes without consuming actual semiconductor substrates.

Despite these advancements, the integration of digital twin technology into ALE process systems for the autonomous generation of process recipe parameters and subsystem control parameters has yet to be realized. The industry demands an ALE process system capable of autonomously optimizing its operations in response to varying conditions, ensuring the highest level of precision and efficiency in semiconductor material etching. This invention addresses these needs by providing an innovative ALE process system empowered with a digital twin, significantly improving the etching process in semiconductor manufacturing.

### SUMMARY

In some embodiments, the present inventive concept highlights an innovative feature of an ALE process system: its capability to autonomously generate process recipe parameters and subsystem control parameters. This autonomous operation is achieved through a system digital twin, a comprehensive digital replica of the entire ALE process system, including its subsystems, their integration, and the process steps applied to a substrate.

The digital twin is instrumental in the ALE process system's functionality. In certain embodiments, it is designed to simulate the behavior and performance of the ALE process, enabling the system to predict outcomes by varying recipe parameters before applying them to the real-world process. This predictive ability facilitates the generation of process recipe and subsystem control parameters that can optimize the etching process for different substrates under varying conditions.

Furthermore, in some embodiments, the system digital twin incorporates models and neural networks that accurately replicate the dynamics of subsystems, such as RF power delivery, gas flow regulation, and temperature control. This allows for precise and autonomous adjustment of these subsystems, ensuring optimal operation conditions.

In another aspect, in certain embodiments, a system controller utilizes the system digital twin to autonomously generate process recipe parameters and subsystem control parameters, serving as an interface between the real world and the virtual world.

In still other embodiments, the system controller generates process recipe parameters and subsystem control parameters by employing various optimization procedures. It may generate an initial guess of the recipe parameters, leveraging a large set of application cases already generated in the background over time. The initial guess or guesses can be generated through a search and query method employing a metadata system that captures key features of the previously generated cases stored in a storage media of the system controller.

In some implementations, various neural networks are generated for the subsystems, the plasma process chamber, and the ALE process itself. These neural networks can be trained with simulation data generated by the digital twins. Measurement data can optionally augment the synthetic data, and in some cases, measurement data may be used for training by assigning it a heavier weight.

Moreover, in some embodiments, the system digital twin is further employed to improve the speed of autonomous recipe generation. This is achieved by using an inverse ALE neural network trained to invert the relationship between inputs and outputs of the ALE process. By employing this network, the system can rapidly generate selected process recipe parameters and subsystem control parameters, enhancing the autonomous operation of the ALE system.

This approach of using the system digital twin for autonomous generation and adjustment of process recipe and subsystem control parameters reflects a novel use of simulation and predictive models in the field of semiconductor fabrication.

### BRIEF DESCRIPTIONS OF DRAWINGS

To provide enhanced clarity, the following description references the accompanying drawings:

FIG. 1A: Shows a diagram of an exemplary ALE process system.

FIG. 1B: Depicts a functional diagram of a system controller configured to autonomously generate a process recipe.

FIGS. 2A and 2B: Illustrate various steps of an ALE process as exemplified in different operational states involving RF and gas distribution subsystems.

FIG. 2C: Showcases a structure on the substrate before and after the ALE process.

FIG. 3A: Provides a schematic representation of a system digital twin.

FIG. 3B: Showcases an ALE digital twin based on the system digital twin.

FIG. 4A: Portrays a system neural network representation of the system digital twin.

FIG. 4B: Portrays an ALE neural network based on the system neural network.

FIG. 5: Displays a flowchart outlining the training protocol for the system neural network, utilizing various subsystem and ALE process neural networks.

FIG. 6A: Shows a flowchart for the determination of resonating frequencies using a trained neural network.

FIG. 6B: Provides a flowchart detailing the process for determining of the valve's set point, guided by a trained neural network.

FIG. 6C: Illustrates a flowchart for establishing set points for the heater and the chiller through a trained neural network.

FIG. 7: Reveals a flowchart outlining the process of generating process recipe parameters and subsystem control parameters through an optimization procedure.

FIG. 8A: Shows a flowchart describing the generation of an initial guess for the optimization procedures, employing a database represented by metadata of various application cases.

FIG. 8B: Showcases exemplary structures of the metadata.

FIG. 9: Depicts a flowchart for the generation of the process recipe parameters and subsystem control parameters utilizing a multi-stage grid search methodology.

FIG. 10: Illustrates a schematic of an inverse ALE neural network for generating selected process recipe parameters and subsystem control parameters.

FIG. 11: Presents a flowchart for determining selected process recipe parameters and subsystem control parameters by applying the inverse ALE neural network.
Table 1: Summarizes parameters describing structures to be etched and structures post ALE processing.
Table 2: Summarizes parameters describing process recipe parameters.
Table 3: Summarizes design parameters describing subsystem structures, topologies, and control parameters.

### DETAILED DESCRIPTIONS

In this section, we delve into the specific embodiments of the current invention to facilitate a deeper understanding. It should be noted that while particular implementations are described for clarity, alterations and modifications falling within the scope of the claims that follow are considered to be within the ambit of this disclosure. The detailed descriptions are intended to highlight the novel aspects of the invention, distinguishing it from conventional technology.

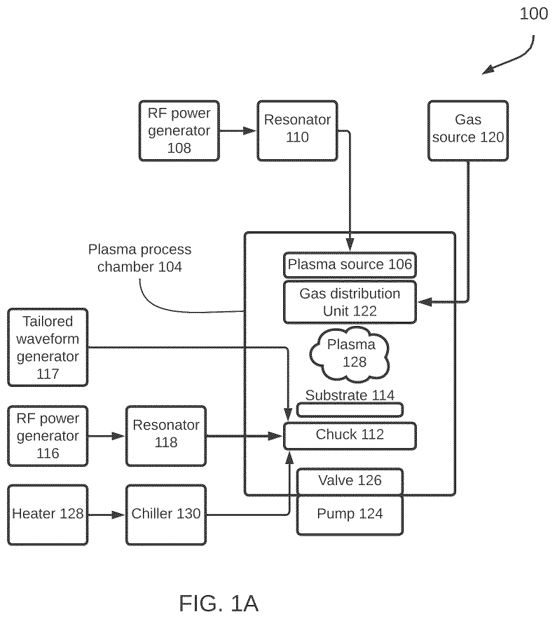

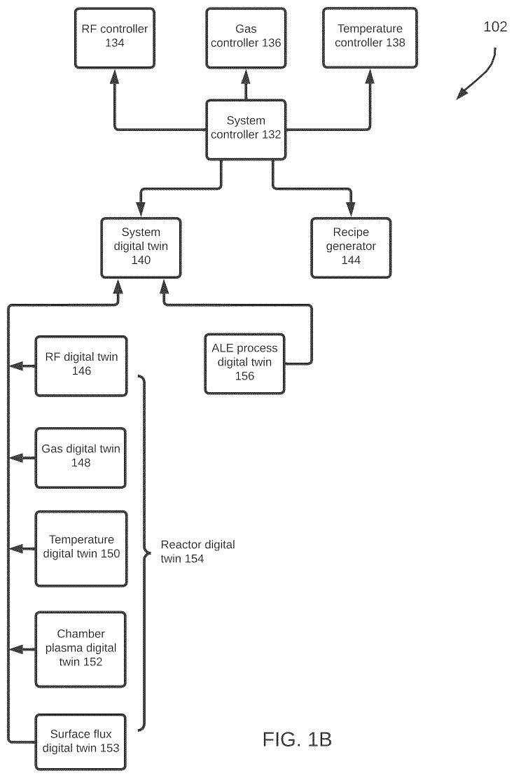

FIG. 1A sets forth an embodiment of an ALE process system, designated as 100. The ALE process system 100 includes a plasma process chamber 104, which is constructed to maintain a vacuum suitable for plasma processing. Within this system, a plasma source 106 is situated to receive RF power from an RF power generator 108 via a resonator 110. The plasma source 106 may be realized in various configurations such as an inductively coupled plasma (ICP) source or a transformer coupled plasma (TCP) source, among others.

The RF power generator 108 can operate at single or multiple frequencies—for instance, frequencies such as 13.56 MHz, 2.0 MHz, and 40 MHz may be used. The role of the resonator 110 is to match the output impedance of the RF power generator 108 with the impedance of the plasma process chamber 104, considering the impedance characteristics of the transmission lines. This resonator 110 is typically composed of inductors and capacitors and may, in some instances, include mechanically adjustable capacitors. Alternatively, in other embodiments, the resonator 110 might exclude mechanically adjustable capacitors.

Adjustments to impedance may be realized by varying the operating frequencies of both the RF power generator 108 and the resonator 110. During an ALE process, the plasma will exhibit variable states which, in turn, will present different impedance levels. To maintain efficient energy transfer and minimize power reflection from the plasma process chamber 104 back to the resonator 110, it may be necessary to fine-tune the frequency for each distinct state of plasma so that the resonator 110 remains in a resonating condition.

The plasma process chamber 104 is further outfitted with a chuck 112 that functions to support a substrate 114. The chuck 112 can be designed as an electrostatic chuck (ESC) or a vacuum chuck, depending on the requirements of the process. In a preferred implementation where an ESC is utilized, the chuck 112 is electrically connected to an RF power generator 116 via a resonator 118. Analogous to the previously mentioned resonator 110, the resonator 118 also necessitates tuning to a resonating state, which is achieved by adjusting at least its operating frequency. It should be noted that the operating frequencies of RF power generator 116 might differ from those of RF power generator 108. For instance, the frequency at which generator 116 operates could be substantially lower than that of generator 108.

The RF power generator 116 is responsible for providing a bias to the chuck 112. This bias is delivered through a blocking capacitor, which, while not depicted in the figure, is standard in the field. Alternatively, in some embodiments, a tailored waveform generator 117 is employed to supply a bias to the chuck 112. The application of a tailored waveform has the potential to significantly narrow the distribution of ion energies—these ions are produced because of the ignition of plasma 128 within the process chamber 104. Depending on the specific implementation, the tailored waveform generator 117 alone may be connected to the chuck 112 without the RF power generator 116/resonator 118 or may work together with them to provide the required bias.

The operation of an RF subsystem, which includes the RF power generators, resonators, and the plasma source, is managed by an RF controller 134 (FIG. 1B). This controller is, in turn, in communication with and subordinate to a system controller 132 (FIG. 1B).

Complementing the above components, the plasma process chamber 104 incorporates a gas distribution unit 122 tasked with delivering process gases from a gas source 120 into the plasma process chamber 104. The gas distribution unit 122 can assume various forms, such as a gas injector or a showerhead, and may also include a side injection feature near inner surfaces of the chamber body. The gas source 120 typically draws on a facility's gas supply through a gasbox and utilizes a combination of valves, pressure regulators, and mass flow controllers (MFCs) to regulate the flow of gas into the chamber.

Furthermore, the plasma process chamber 104 houses a pump 124, which may be a turbomolecular pump or another suitable type, designed to evacuate gases and by-products from the chamber. A valve 126, generally positioned atop the pump 124, operates in conjunction to modulate the evacuation rate from the chamber. The chamber pressure is monitored by a manometer (not illustrated), which triggers adjustments to the set point of an actuator of the valve 126 to maintain a constant pressure suitable for the ALE process.

A gas distribution subsystem that includes but is not limited to the gas distribution unit 122, gas source 120, pump 124, and valve 126 is overseen by a gas controller 136. This controller is also connected to the overarching system controller 132, ensuring integrated management of the ALE system.

The plasma process chamber 104 is further equipped with a temperature control subsystem for maintaining the desired thermal conditions for the substrate and inside the chamber. In the embodiment exemplified in FIG. 1A, the temperature of the chuck 112 is regulated by a temperature controller 138, which operates a heater 128 and a chiller 130, as well as a temperature sensor (not depicted in the figure). It's important to note that the chuck 112 may be designed with multiple zones, each of which can be maintained at a distinct temperature. Additionally, temperature control for other components within the process chamber, such as the gas distribution unit 122 and various chamber surfaces, may be required and is implemented as is common in the industry. The temperature subsystem is controlled by a temperature controller 138 coupled to the system controller 132.

An exemplary ALE process typically involves alternating between a surface modification step A and a sputtering step B in a cyclic manner. Step A chemically alters the surface of the substrate 114 using chemically active neutrals formed in the plasma 128, which is generated by the plasma source 106 powered by the RF power generator 108. A halogen gas, such as chlorine, is often introduced to produce neutrals for this purpose. The completeness of a surface modification step is characterized by a percentage of surface bonds altered or covered. This is an important parameter which determines the ideality of an ALE process. During this surface modification step, the bias to the chuck 112 is set to zero to minimize the impact of ions on the substrate 114, thereby preserving the integrity of the ALE process.

Conversely, during the sputtering step B, an inert gas like argon is introduced to generate energetic ions that physically remove the chemically modified layer from the substrate by sputtering. At this juncture, a bias is typically applied to the chuck 112 through the RF power generator 116 and resonator 118, or through the tailored waveform generator 117. In some implementations, they may be combined to facilitate the sputtering process.

Between these steps, a purge step may be employed to transition the gases from step A to step B or vice versa without intermixing the two process gases.

In some cases, particularly when etching high aspect ratio structures, an additional deposition step C can be optionally included along with steps A and B. This step C is strategically inserted into the ALE cycle sequence but at a less frequent rate compared to steps A and B. Its primary function is to protect the sidewalls of the etched structures, thus preventing lateral etching that may arise due to the angular distribution of the ion momentum.

FIG. 1B showcases the ALE process system 100 functioning as an autonomous entity, attributed to the advanced capabilities of the system controller 132. This is further detailed in a functional diagram of the autonomous control system, labeled as 102. The system controller 132 is integrated with the RF controller 134, the gas controller 136, and the temperature controller 138, ensuring an integrated operation of these subsystems. A distinct feature of the embodiment is the incorporation of a system digital twin 140 into the control system, which effectively replicates virtually the behavior of the ALE process system 100. This feature positions the system controller 132 as an intermediary between the real-world process system and its virtual counterpart. Within the system digital twin 140, there are additional components: the RF digital twin 146, the gas digital twin 148, and the temperature digital twin 150, each simulating respective subsystem operations.

The RF digital twin 146 is designed to emulate the RF subsystem, which includes at least RF power generators and resonators. In some cases, it may also include a tailored waveform generator for the bias, although the tailored waveform generator is typically not operated in the RF range. Its implementation might involve simulation models such as a version of the SPICE models, or it could utilize neural networks trained with synthetic data from simulations. In some implementations, actual measured data is employed to enhance the training procedure. The measured data may carry more weight in training. Alternatively, it might be a hybrid of both models and neural networks.

Similarly, the gas digital twin 148 replicates the functions of the gas distribution subsystem, encompassing elements like the gas source 120, the gas distribution unit 122, the pump 124, the valve 126, and the manometer (not pictured). This digital twin could be based on fluid dynamics models, analytical models, empirical models, or neural networks, with training from simulated data, measured data, or a combination of both. The digital twin could also employ a combination of models and neural networks.

The temperature digital twin 150 mirrors the temperature control subsystem, which includes the heater 128, the chiller 130, and temperature sensors (not pictured). Besides the chuck temperature controls, it may additionally incorporate temperature regulation for other chamber parts such as the gas distribution unit 122. Implementation for this digital twin may include numerical and analytical models, and neural networks trained with simulated, measured data, or a combination of both. The digital twin can also be a hybrid model based on both models and neural networks.

The chamber plasma digital twin 152 functions to simulate the internal dynamics of the plasma process chamber 104. It processes inputs from the other digital twins (146, 148, and 150) to create a dynamic model of how electrons, ions, and neutral particles behave within the plasma process chamber. This model might illustrate particle distribution in either three dimensions or a simplified two-dimensional version. The modeling can be continuous over time or consist of discrete snapshots at moments. Additionally, it characterizes various properties of the particles, such as energy, momentum, and density.

Taking the outputs of the chamber plasma digital twin 152, a surface flux digital twin 153 generates ion flux and neutral flux towards the surface of the substrate. The ion and neutral fluxes enable the etching process to continue. At different moments of the ALE process step, the fluxes vary. The surface flux digital twin 153 generates the fluxes as a function of time. The digital twin may be a model that calculates the fluxes based on the 3D distributions of ions and neutrals. The digital twin may also be a neural network trained by synthetic data from simulations. The training procedure can be enhanced by additional measurement data.

In some instances, the subsystem digital twins need to work together to generate accurate predictions. For example, the surface temperature of a substrate exposed to a high ion flux can be affected by the ion flux exchanging energy with the substrate. Hence, determination of the surface temperature requires collaborative work between the temperature and the surface flux digital twins.

The system controller 132 integrates various subsystem digital twins. For example, in one scenario where an ICP plasma source is utilized, it obtains RF power through the resonator 110 from the RF power generator 108. This RF power initiates an electromagnetic (EM) field within the chamber that results in the creation of electrons near the ICP plasma source. These electrons then diffuse and interact with the field to produce ions and neutral particles, a process well-known in the field. The digital twin 152 can also simulate the formation of the boundary layer (sheath) of plasma near the substrate and the inner surfaces of the chamber 104. The model accounts for the history of the particle distributions, which can be influenced by various real-time controls, such as frequency adjustments for the RF subsystem, pressure regulation through changing the set point for the valve 126, and temperature control for the substrate and within the chamber 104 through varying the set points for the heater 128 and the chiller 130.

Consequently, the digital twin 152 can be composed of sophisticated models that typically require significant computational resources and may operate slowly. As an alternative, a neural network can be trained using the outcomes of numerical modeling as synthetic data, bolstering the efficiency of the system. Real-world measurements, such as magnetic field distributions recorded via small coils (B-dot measurements) within the chamber or electron density gauged by a hairpin probe that measures the resonance frequency of an associated microwave circuit, can further refine the neural network's learning.

This digital twin, therefore, might be a hybrid system combining detailed numerical models and neural networks. In certain cases, analytical models might also be utilized to supplement the predictive accuracy of the chamber plasma digital twin 152. There are many possible variations to trade off the accuracy and speed in constructing the digital twins. A distinct feature of an ALE process is that it is operated with one or more self-limiting steps. This feature allows accurate outcomes for structures in the substrate to be predicted using fast and less accurate models. This opens the possibility for high-speed computation in real time by utilizing computationally efficient models.

Understanding the dynamics within the ALE process system requires a deep dive into the intricacies of particle behavior. The distributions of electrons, ions, and neutrals within the plasma process chamber 104 are pivotal, allowing for the modeling of their fluxes toward the substrate surface. Such modeling considers the plasma sheath's distribution, which is pivotal for flux calculation. These fluxes, crucial for the ALE process, may also be measured with specially designed measurement apparatus and used to augment the training data for neural networks within the digital twins.

In addition to flux dynamics, changes in the bonding strength of surface atoms of the substrate as a function of neutral interactions are an important parameter during the surface modification step A. The extent to which surface bonds are saturated (or covered) by chemically active neutrals is a defining factor for the ideality of the ALE process.

Digital twins, such as the RF digital twin 146, the gas digital twin 148, the temperature digital twin 150, the chamber plasma digital twin 152, and the surface flux digital twin 153 collectively establish the reactor digital twin 154. This integrated digital twin outputs a range of crucial data including ion and neutral fluxes to the substrate surface, as well as the temperature of the substrate surface.

The subsystem digital twins listed herein are exemplary only. In some ALE process systems, digital twins for modeling interior chamber surface aging are also important for predicting accurately structure progression undergoing an ALE process. In some cases, erosion of edge rings along the ESC can also be an important factor which requires a separate digital twin to improve the accuracy of the prediction. Therefore, the subsystem digital twins listed herein are elaborative but are not exclusive.

The overarching system digital twin 140 extends to include the ALE process digital twin 156, which assimilates the outputs from the reactor digital twin 154 to simulate the evolution of structures on the substrate resulting from an ALE processing. As a comprehensive process simulator, the ALE process digital twin 156 inputs data on incoming substrate characteristics, such as mask layers, thickness, material properties, dimensions, and profiles of structures, in addition to properties of the layer targeted for etching. A list of exemplary input parameters is depicted in Table 1.

Beyond this, the ALE process digital twin 156 processes recipe parameters like the durations for steps A and B, the total ALE cycle count, insertion points and durations for step C, along with any pulse modulation specifics such as pulse duration and duty cycles, if applied within the ALE steps. Other parameters, particularly those related to subsystems like RF power settings, are already encompassed by the respective digital twins (146, 148, 150).

For the implementation of the ALE process digital twin 156, while a Monte Carlo simulator or other numerical simulators might provide high accuracy, they often demand considerable computational resources, which can be a drawback for real-time applications. An alternative approach involves deploying a neural network for the ALE process digital twin 156. The neural network may be trained using synthetic data generated using methods like Monte Carlo simulation. The training may be enhanced by subsequent refinement using real-world measurement data.

In some implementations, the ALE process digital twin 156 may be developed as a hybrid model, employing both analytical and numerical models or combining analytical models with neural networks. The self-limiting behavior of the ALE process lends itself well to analytical modeling, efficiently capturing fundamental ALE responses. Numerical models or neural networks can be incorporated to address deviations from the ideal process, like lateral etching or depth loading effects. This tradeoff between models enhances the precision of predictions while maintaining computational efficiency.

The system controller 132 is additionally equipped with a recipe generator 144, which generates the process recipe in an autonomous manner, along with the subsystem control parameters. Detailed descriptions of various embodiments will be elucidated in the subsequent paragraphs of this disclosure.

Across all embodiments, digital twins are utilized to enhance the system's performance. In certain embodiments, various methods or algorithms are applied to initially formulate the process recipe and the subsystem control parameters, which are then subjected to iterative optimization. In other scenarios, these optimization procedures may involve grid search or multi-stage grid search methods.

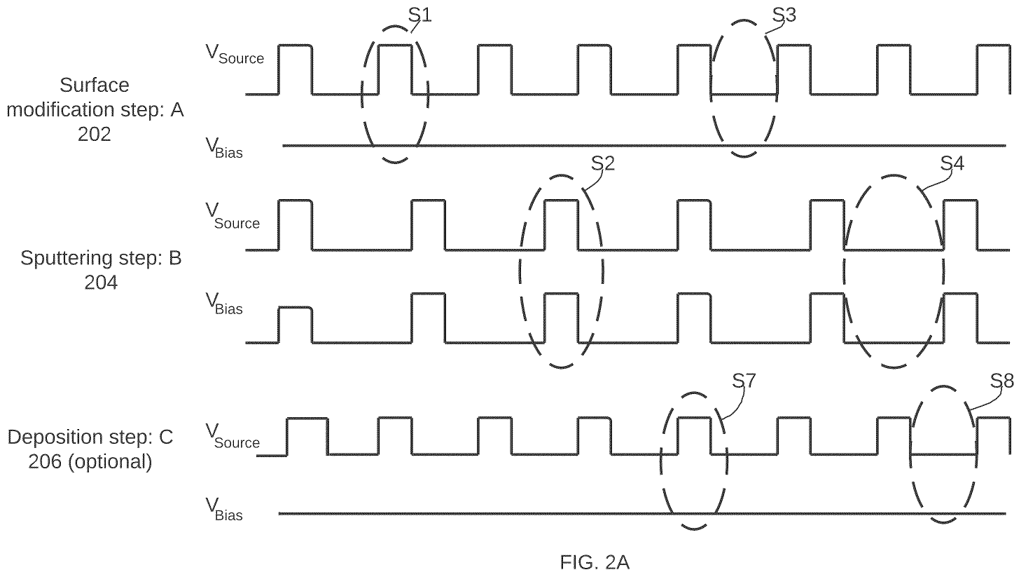

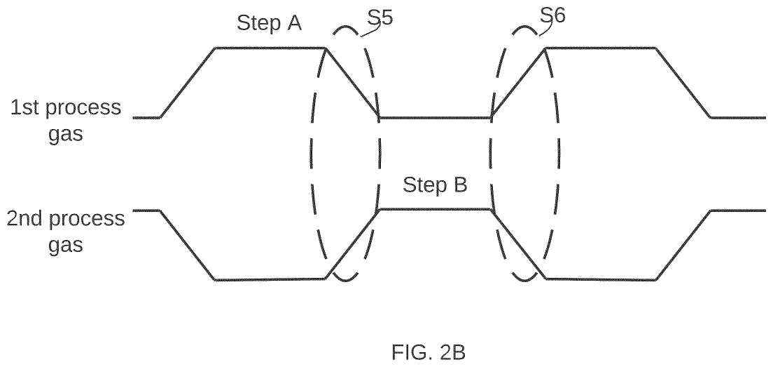

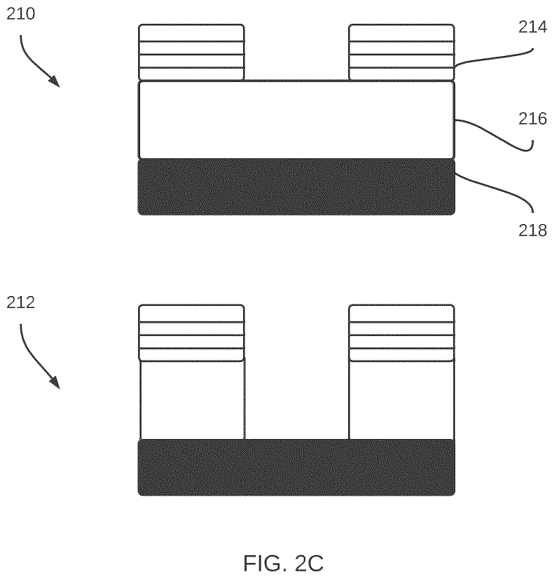

Among the innovative approaches is the construction of an inverse ALE neural network. This network is designed by flipping at least a portion of the inputs and outputs of the system digital twin 140; what was previously an output becomes an input to the inverse ALE neural network, and vice versa. The outputs of this inverse ALE network now are selected process recipe parameters and subsystem control parameters, thus enabling the ALE process system to generate the most optimal inputs (i.e., process parameters) for a given desired output (i.e., process results). FIG. 2A depicts various states in steps A, B, and C. State S1 represents a state in the surface modification step A (202), where the plasma source 106 receives RF power from the RF power generator 108 while the chuck 112 is not biased. This state is crucial for enabling surface modifications without a chuck bias to avoid energetic ions impacting the substrate surface. State S2 reflects a state in the sputtering step B (204) where the chuck is biased by either the RF power generator 116 and/or the tailored waveform generator 117. This bias is essential for the sputtering process as it directs the energy and trajectory of ions towards the substrate vertically. The RF powers applied to the chuck and to the plasma source are synchronized as shown in FIG. 2A. This is an example only. There are many ways, as known in the art, to design a pulsing scheme for the plasma source and for the bias of the chuck. The scheme as depicted in FIG. 2A should not limit the scope of the present inventive concept.

State S3 captures another state within the surface modification step A (202) where both the plasma source 106 and the chuck 112 cease to receive RF powers. However, the significance of this state remains as it can contribute to the modification of the substrate surface with neutrals that were generated during S1. The state S4 illustrates a state in the sputtering step B (204), wherein both the bias and the source are turned off. This state can also be a significant state to allow reaction byproducts to diffuse out of a high aspect ratio structure on the substrate.

States S7 and S8 pertain to the deposition step C (206). S7 is used to generate ions and neutrals for the deposition, while S8 allows the generated neutrals to diffuse into desired positions in a high aspect ratio structure. These states are applied to deposit a layer to protect the sidewall of the structures being etched by the ALE process.

Moving on to FIG. 2B, it showcases an exemplary ALE process including transitions between the process gases. During state S5, the first process gas for the surface modification step A (202) is ramped down, and the second process gas for the sputtering step B (204) is ramped up. This transition is critical for switching between the two distinct steps (A and B) of the ALE process. Conversely, state S6 is when the first process gas for the surface modification step A (202) is ramped up while the second process gas for the sputtering step B (204) is ramped down, marking the preparation for a return to the surface modification step from the sputtering step.

FIG. 2C showcases an exemplary incoming structure 210 and a structure 212 post ALE processing. The incoming substrate 210 includes a mask layer 214, a targeted layer 216 to be etched by the ALE process, and a layer 218 underneath the targeted layer. As shown in Table 1, a data set describing the incoming mask includes but is not limited to materials for the mask stack, its thickness, the mask critical dimension, profile, uniformity, and loading created from previous process steps. In some implementations, the mask stack is a photoresist layer. In other implementations, the mask layer is a hard mask layer like a carbon layer, a silicon oxide layer, or a silicon nitride layer, or any combination of the above. All these properties need to be disclosed to enable the ALE digital twin. The data set further includes information about the targeted layer 216. It includes but is not limited to materials for the stack, its thickness, and the underlying material, which may affect the profile near the bottom of the structure post ALE.

As further illustrated in Table 1, parameters describing the structure post ALE, designated as 214, include but are not limited to dimensions, profile, uniformity, and loading. The profile may be described by several parameters like top and bottom dimensions, bowing, and positions of bowing. The loading includes isolation to dense pattern dimension difference, and depth difference post ALE processing. Reduction in mask layer thickness and profile changes are indications of the selectivity of the ALE process, which is an important performance indicator.

It should be noted that the parameters describing the incoming structures may be a group of structures instead of a single structure. The structures may be placed in selected locations across the substrate, like a 300 mm wafer. Sometimes, structures with different dimensions or a different part of the structure may be used to characterize various loading effects. Therefore, when the system digital twin 140 is applied to simulate an ALE process, it may be applied to a group of structures instead of a single structure.

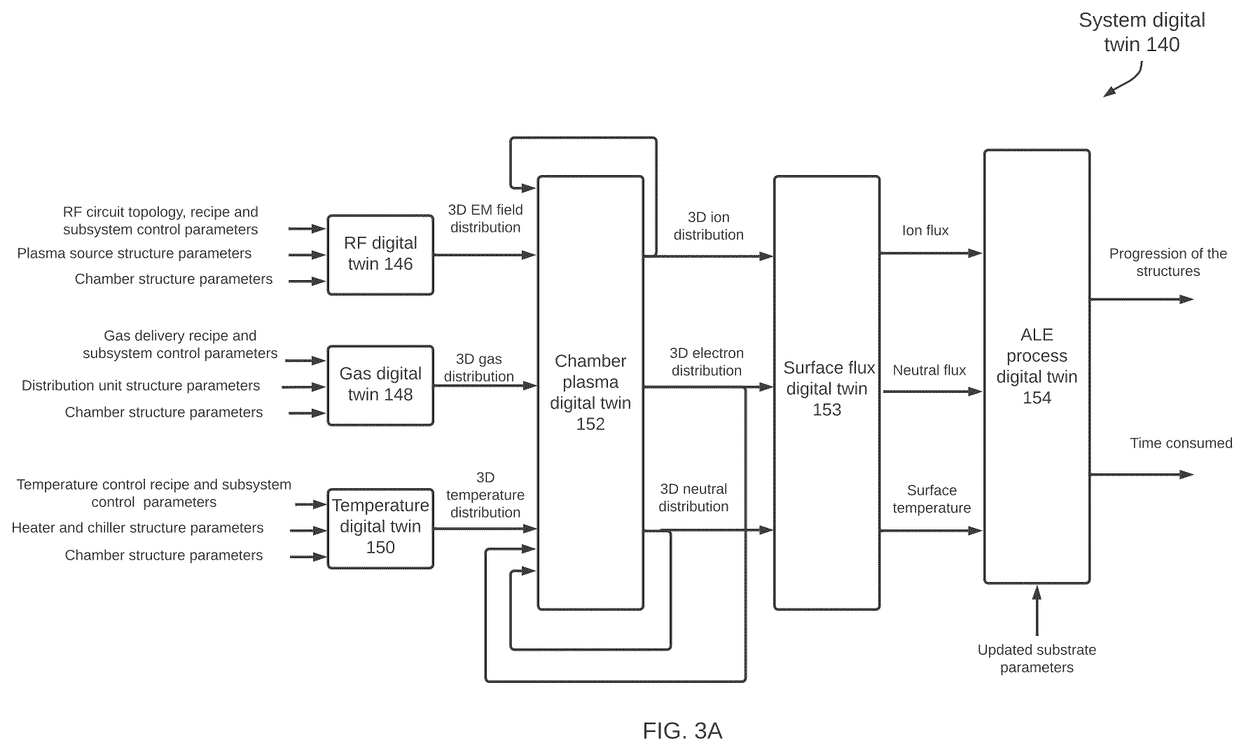

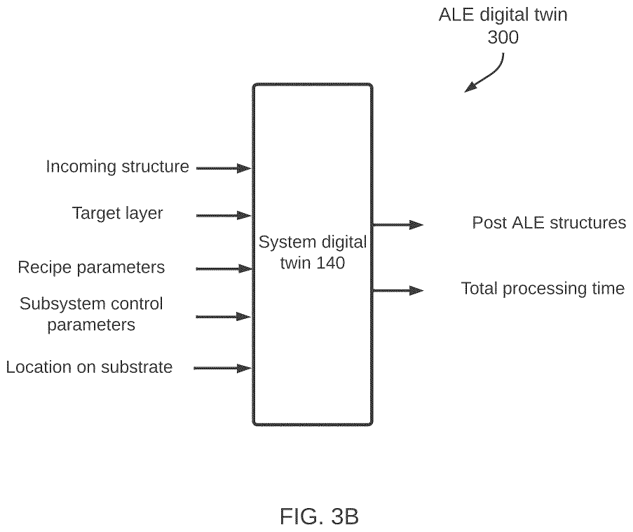

FIG. 3A provides a schematic overview of the operation flow of the system digital twin 140. Starting from the left side of FIG. 3A, subsystem digital twins receive process recipe parameters and subsystem control parameters and generate inputs for the chamber plasma digital twin 152.

Going into the next level of detail, the RF digital twin 146 receives recipe parameters like RF power and initial operating frequency for a specific step stipulated by the process recipe. A set of design parameters like RF circuit topology, values of each component, structures, and parameters of the plasma source, and chamber structure parameters are typically stored in a storage media of the system controller 132. A set of exemplary design parameters for the RF subsystem is listed in Table 3. The inputs to the RF digital twin 146 further include subsystem control parameters like the operating frequency for the step. The operating frequency is the resonating frequency of the resonators reflecting the impedance of the plasma process chamber. The output of the RF digital twin 146 includes the electromagnetic (EM) field distribution inside the chamber, particularly near the plasma source. In one implementation, the RF digital twin 146 includes a SPICE model for the RF circuits, which determines the RF power deposited into the plasma source at the step. A Maxwell's equation solver is subsequently employed to compute the EM field distribution inside the chamber by taking into consideration the chamber structure parameters.

The gas digital twin 148 receives process recipe parameters like the flow rate of the first and second process gases and the chamber pressures for the surface modification step and the sputtering step, respectively. The design parameters for the gas delivery systems include the design parameters for the gas distribution unit. If it is a showerhead, the design parameters will include its size, volume, distribution of injection channels/holes, and their sizes. The shape and size of the plasma process chamber are also important input parameters for the gas digital twin 148. The subsystem control parameters include, but are not limited to, the set point for the actuator of the valve 126. The output of the gas digital twin 148 includes 3D gas distribution (e.g., density, partial pressure, velocity, and residence time) inside the gas distribution unit 122 and in the plasma process chamber 104. In some implementations, the gas distribution along gas lines from the gas source 120 to the entry of the gas distribution unit 122 will also be modeled. The gas distribution can be simulated using methods like fluid dynamics, using finite element techniques or other more advanced computational techniques.

The temperature digital twin 150 receives process recipe parameters like chuck temperatures at different steps. In some instances, the chuck 112 may be divided into zones, and each zone may have a different temperature specified by a process recipe. The input parameters to the temperature digital twin 150 further include design parameters for the heater and chiller. For the heater 128, the design parameters include its locations inside the chuck or inside any other chamber parts. The design parameters may also include a range of its operating power. The design parameters for structures further include thermal conductivity for various materials and their interfaces. For the chiller, the design parameters may also include the type of coolants, flow rates of the coolants, and the number of conduction channels and their locations. The temperature digital twin may apply numeric simulation methods like the finite element method to simulate the temperature distribution of the chuck, substrate surface, and inner surface of the plasma process chambers.

It should be noted that treating the digital twins 146, 148, and 150 independently may be an oversimplification of the real world. For example, the RF power deposited into the chamber may affect the temperature of the substrate surface. Some of these interactions among different subsystem digital twins should be considered carefully.

The outputs of the subsystem digital twins feed into the chamber plasma digital twin 152. At a specific time of a process step, the chamber plasma digital twin 152 models the plasma inside the chamber 104 and outputs 3D distributions of electrons, ions, and neutrals. It should be noted that the distributions at a specific time are not only a function of the EM field, gas, and temperature at that current moment but also a function of the distributions of electrons, ions, and neutrals prior to that moment. Hence, the distributions of the electrons, ions, and neutrals will need to be decided in a recuring manner. As shown in FIG. 3A, the outputs of the chamber plasma digital twin can serve as inputs for the same digital twin for the next step. Each simulation event is for a predetermined small step defined by the system controller 132 based on the process recipe.

After the 3D distributions of ions and neutrals are known, the surface flux digital twin 153 calculates and outputs the ion flux and neutral flux towards the surface of the substrate. In addition, the digital twin 153 may also output the surface temperature of the substrate by working together with the temperature digital twin 150. The plasma sheath above the substrate is critically important for determining the ion flux, which has a great impact on the etching behavior. The formation of the plasma sheath is well understood in the art and can be modeled accurately using the chamber plasma digital twin 152.

The outputs of the surface flux digital twin 153 feed into the ALE process digital twin 154 to simulate the ALE process. The status of the substrate structures serves as the inputs to the ALE digital twin 154. The updated substrate structure parameters are used by the ALE process digital twin to determine its outputs.

It is important to note that the flow depicted in FIG. 3A represents a snapshot of the ALE process. The ALE process includes at least step A and step B, and sometimes also includes a step C, with multiple plasma states. Therefore, the output of the ALE process digital twin is a progression of the structures for this small step. The time consumed for this small step can also be recorded as one of the outputs of the ALE process digital twin 154.

An exemplary list of the process recipe parameters is showcased in Table 2. The system controller 132 will need to break down the process recipe into many small steps to be simulated by leveraging the system digital twin 140.

During each small step, the accumulated ion and neutral fluxes should be counted. Details of ion and neutral distribution are important for the ALE process. For the ions, during the small step, their energy and angular distributions are critically important. The distributions can be a function of the location on the surface of the substrate. The outputs of the surface flux digital twin 153 should include such critical details. Similarly, for neutrals, the density, thermal energy, and activation energy are important parameters for the surface modification step of the ALE process.

To complete the ALE process virtually, a complete process recipe must be executed step by step. FIG. 3B showcases an ALE digital twin 300 capable of emulating the entire ALE process in the plasma process chamber. The ALE digital twin 300 is built upon the system digital twin 140. It covers the complete ALE process including multiple cycles. Each cycle includes at least the surface modification step A (202) and the sputtering step B (204). It may also include a deposition step C, less frequently deployed compared to steps A and B. FIG. 3B includes inputs and outputs as already listed in Table 1.

For the implementation of the ALE process digital twin 156, a model-based approach, a neural network, or a hybrid of both can be adopted. The choice between these options will depend on the complexity of the ALE process, the need for real-time simulation feedback, and the accuracy requirements of the predictions.

For the surface modification step A (202), it is important that modified bond coverage on the surface of the substrate can be modeled with acceptable precision. The modification of the surface bonds typically takes 10 to 100 milliseconds, depending on the density, thermal energy, and activation energy. The digital twin should also take diffusion time into consideration, which includes the duration that neutrals diffuse from the surface of the substrate into the etching front of the structures being etched. The surface herein may not strictly mean a single monolayer. When plasma is applied, the surface modification can be extended to several monolayers of the atoms while maintaining self-limiting behaviors.

The neural networks, if chosen, can be constructed on the foundation laid by the system digital twin 140, employing advanced computational techniques such as Monte Carlo simulations or numerical models tailored for the process system. The simulation data generated by the system digital twin 140 can be employed to train the neural network of the process system 100. The training of the neural networks can be greatly enhanced by incorporating real-world measurement results, which serve to validate and refine the simulated data, thereby improving the robustness and reliability of the digital twin as a predictive tool.

This comprehensive digital mirroring of the ALE process system via the digital twin framework enables a virtual yet accurate reflection of the ALE process, fostering better understanding, control, and optimization of the complex interactions and parameters that define the ALE system's performance.

It should be noted that the designs of the subsystem, chamber plasma, and ALE process digital twins are exemplary herein. There could be many variations in implementation strategies. In some implementations, the chamber plasma digital twin and the surface flux digital twin could be combined into a single digital twin. In other implementations, the surface flux digital twin may be combined with the ALE process digital twin. Additionally, the RF subsystem digital twin may be broken down into several digital twins to represent the plasma source and the bias units separately. Similarly, the temperature digital twin can be divided into two digital twins, with dedicated digital twins for the chuck and the gas distribution unit, respectively. All such variations are obvious and should fall within the inventive concept of the present inventions.

Implementations of the digital twins by neural networks can follow the same strategy of dividing the process system into subsystems.

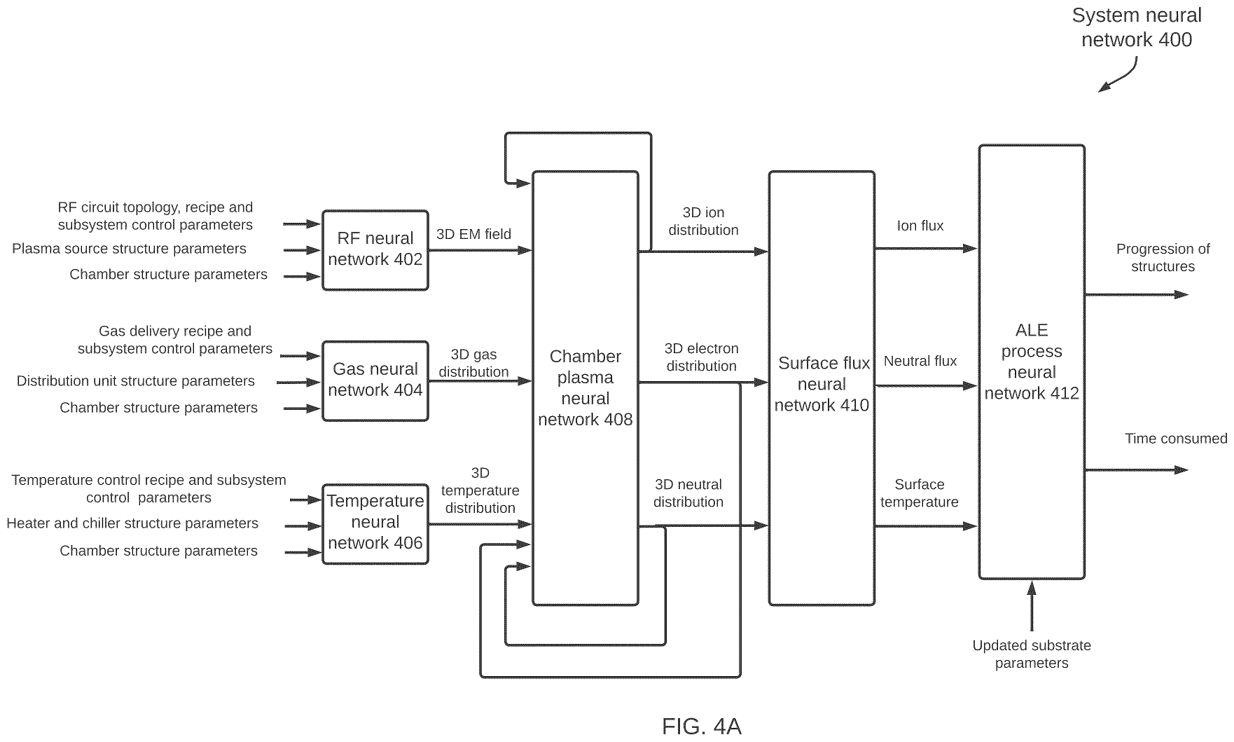

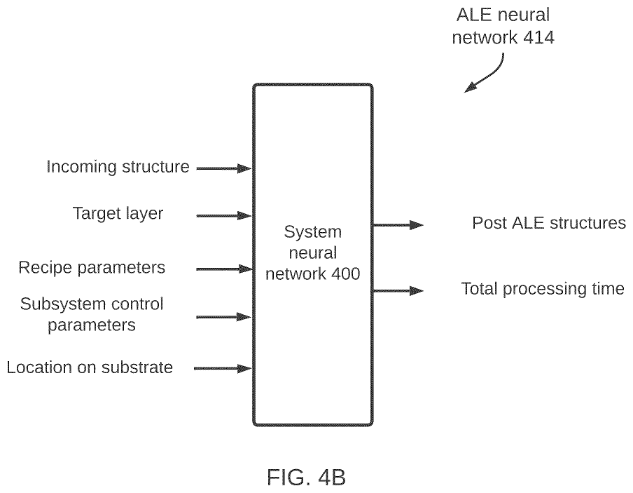

FIG. 4A illustrates an exemplary ALE process system represented as a system neural network 400. In this embodiment, the subsystem digital twins are reconstructed using various neural networks. The RF digital twin 146 serves as the basis for training the RF neural network 402. Taking the plasma source 106 attached to the RF power generator 108 and the resonator 110 as an example, one can begin by constructing a SPICE model to simulate the RF power generator 108 and resonator 110, including their transmission lines. The SPICE model outputs an initial AC current and voltage for coils of the plasma source 106, necessitating an assumed initial impedance for the plasma 128. Following this, a numerical simulator applies Maxwell's equations to predict the EM field distribution within the plasma process chamber 104.

The wealth of simulation data generated by the RF digital twin 146 becomes the training set for the RF neural network 402. The inputs for the neural network 402 include RF circuit topology and parameters such as the values of the inductors, capacitors, resistors, and transistors within the generator and resonator, along with detailed modeling of effects and transmission lines. Additional parameters that characterize the plasma source, like its size, position, resistivity, inductance, and the number of coil's turns, are also incorporated.

Furthermore, the RF neural network 402 considers the chamber structure parameters-dimensional specifics, positions of the chuck and the gas distribution unit, and material properties of these components. Some parameters are measurable and thus provide a more substantial weight during the training of the RF neural network 402. For instance, sensors might track the current and voltage alterations in the coils or the reflected power at the resonator's output node 110. A B-dot sensor with multiple small coils could be positioned within the chamber to map the magnetic field distribution. The information gleaned from these sensors not only informs the training process but ensures that the RF neural network 402 is closely aligned with the real-world behaviors observed.

Utilizing a neural network for modeling the bias portion of the RF subsystem is conducted with a focus on the electric field generated initially in response to the applied RF power. Unlike the magnetic field concerned with plasma generation, the bias deals with the electric field affecting the substrate surface.

Transitioning to the gas dynamics within the ALE process system 100, we approach the gas distribution neural network 404, which is informed by the gas digital twin 148. Numerical fluid dynamics is the foundation for determining the gas distribution within the process chamber 104. This complex interplay involves the gas inflow from the gas distribution unit 122, the outflow managed by the pump 124 and the valve 126 and is influenced by the chamber's conductance and volumetric parameters. While numerical simulations offer accuracy, their demand for computational resources and time constraints necessitate a more efficient approach for real-time applications, hence the establishment of the gas distribution neural network 404.

The gas distribution neural network 404 is trained with simulation data reflecting various parameters, including the types and flow rates of gases, the design of the gas distribution unit 122, the pump's capacity 124, and the set point of the actuator of the valve 126, along with chamber dimensions and conductance. The gas distribution unit 122 implemented as an injector or a showerhead or a combination of both can affect the gas distribution in the process chamber 104. The size, quantity, and distribution of channels/holes inside the injector and the showerhead are important design parameters. Gas pressure within the process chamber, monitored by a manometer, provides measurement data that enhances the training of the gas distribution neural network 404, often weighted more significantly than the simulation data to ensure the model's relevance to actual conditions.

Parallel to these developments is the creation of the temperature control neural network 406, drawn from the temperature digital twin 150. This neural network is dedicated to mapping the thermal landscape within the plasma process chamber, particularly at the substrate surface. Its training originates from numerical models that simulate heat interactions and distributions. Inputs for the temperature neural network 406 include chuck and chamber parameters affecting thermal conduction. In scenarios involving an ESC, the thermal characteristics of the ESC and the heat conduction efficiency, potentially affected by helium pressure used as a medium, are critical.

Set points for heating and chilling elements, like the heater 128 and chiller 130, are integral inputs for the temperature control neural network 406. Additional chamber specifications, such as size and construction materials, also influence the model. Temperature readings from sensors within the chuck 112 and the chamber 104 provide valuable real-world data, which, when used to train the temperature neural network 406, carry heavier weights over simulated data due to their direct measurement of the physical environment. This balance of simulated and measured data ensures that the various neural networks closely mimic the actual processes, thereby enabling accurate predictions and controls within the ALE process system.

FIG. 4A elucidates the intricacies of the system neural network 400, where the outputs of the subsystem neural networks act as inputs to the chamber plasma neural network 408. The chamber plasma digital twin 152 serves as the foundation for the chamber plasma neural network 408, enabling a sophisticated representation of the plasma within the etching chamber.

To simulate the movement of particles within the plasma, either a Monte Carlo or a numeric plasma simulator can be used to visualize the three-dimensional distribution of electrons, ions, and neutrals. This is crucial because electrons, which are significantly lighter, move more rapidly than ions, leading to the creation of a sheath on the surfaces within the chamber. This sheath plays a pivotal role in ion acceleration toward the substrate, a process essential for sputtering but potentially counterproductive during surface modification.

The training of the chamber plasma neural network 408 integrates simulation data for faster computation and higher efficiency. However, to refine its predictive capabilities, it may also assimilate measurement data gathered from sensors within the chamber, such as optical sensors that detect light emission from neutrals and hairpin sensors that gauge electron density. This measurement data may be given a heavier weight over the simulated data to ensure that the outputs of the plasma neural network 408 are as realistic as possible.

The dynamic nature of the plasma environment is captured by the recurrent neural network (RNN) design of the chamber plasma neural network 408. This means it can process temporal sequences, taking snapshots of plasma conditions at a given time and incorporating them into the model for future predictions. It is an ongoing cycle where the network's previous outputs become part of the input data for the next time step, mimicking the continuous evolution of the plasma state.

Once the chamber plasma neural network 408 has computed the 3D distributions, the ion and neutral fluxes to the substrate surface can be determined based on a surface flux neural network 410. The ion and neutral fluxes, along with the surface temperature of the substrate, are then taken as inputs for the ALE process neural network 412. The ALE process neural network 412 can be trained based on the data generated by the ALE process digital twin. The outputs of the ALE process neural network 412 further include the progression of the structure parameters as listed in Table 1 and the time consumed for the small step.

Ultimately, the chamber plasma neural network 408 and the surface flux neural network 410 yield valuable outputs beyond just fluxes; it also provides critical insights into the surface temperature by working together with the temperature neural network 406. The accumulated fluxes during the small steps should also include valuable information about ion energy and angular distribution and neutral thermal energy and activation energy. These parameters are essential for fine-tuning the ALE process to achieve the desired etching precision and substrate surface quality.

The entire ALE process, including several or many ALE cycles, can be simulated step by step by utilizing an ALE neural network 414 as depicted in FIG. 4B, constructed using the system neural network 400. The inputs and outputs have already been listed exemplarily in Table 1. The system controller 132 guides the progression based on the process recipe, which is generated autonomously according to the present inventive concept. The neural network-based system digital twin provides a fast yet accurate representation of the real-world ALE processes.

It should be noted that FIG. 4A showcases an embodiment 400 of a full neural network implementation of the system digital twin 140. In some other embodiments or implementations, some functional blocks may not be implemented as neural networks. For example, the surface flux neural network 410 may be an analytical model. Hence, embodiment 400 is exemplary. There may be many variants of the implementations by combining models, lookup tables, analytical models, numerical models, and Monte Carlo models for selected building blocks of the system digital twin 140. All such variants fall inside the inventive concept of the present inventive concept.

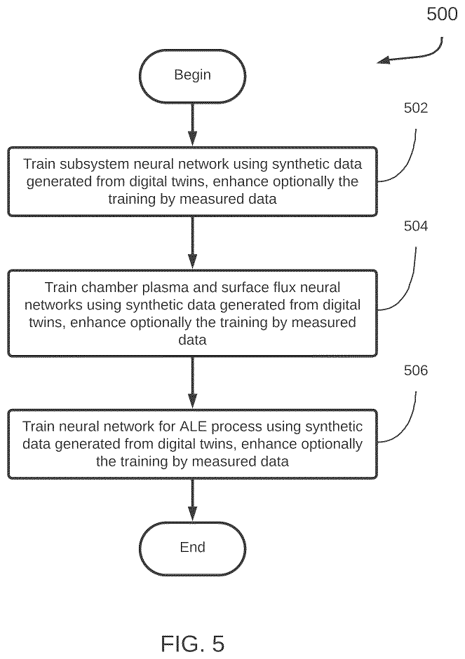

FIG. 5 presents a flowchart outlining the methodology for training the system neural network 400. The process 500 commences in step 502 with the training of subsystem neural networks 402, 404, and 406, employing synthetic data generated from the subsystem digital twins. In step 504, the chamber plasma neural network 408 and the surface flux neural network 410 undergo training utilizing the synthetic data originated from the subsystem digital twins, the chamber plasma digital twins, and the surface flux digital twin. At this step, the trained subsystem neural networks may also be employed. Continuing to step 506, the ALE process neural network 412 is trained with synthetic data generated from the chamber plasma digital twin and the ALE process digital twin. Alternatively, the synthetic data can also be generated utilizing trained neural networks according to steps 502 and 504. The training regimen for each neural network is further enhanced by integrating measured data pertaining to the subsystems, the chamber plasma, and the ALE process itself. Various techniques can be employed to increase weights of measured data. For example, the cost function resulting from the measurement data may carry more weight in training. In another implementation, the measurement data may be reused by adding some low level of noise artificially.

It should be noted that it is optional to use the measured data. In some implementations, the training can be conducted solely based on the synthetic data from the simulations.

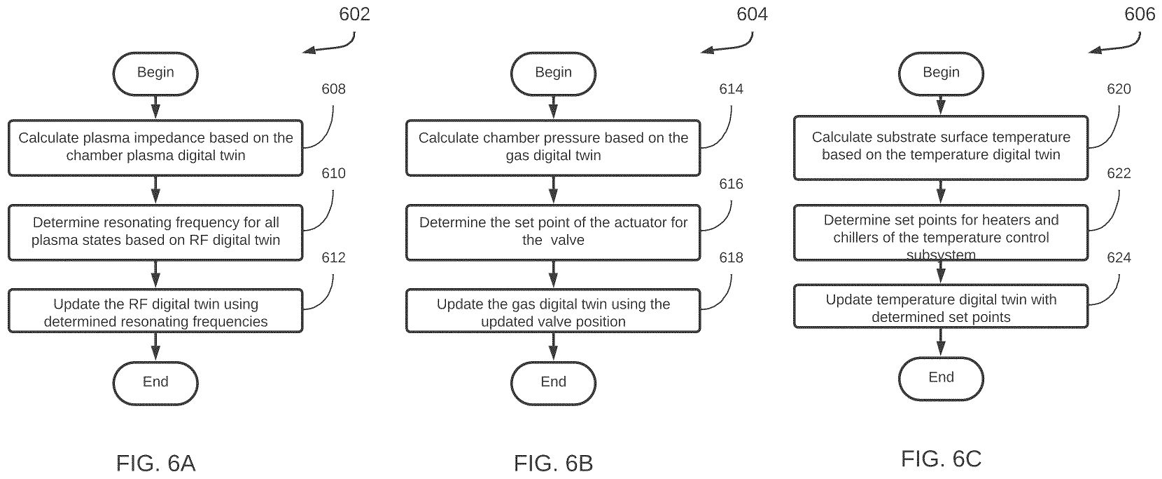

FIG. 6A depicts a flowchart for identifying resonating frequencies corresponding to each plasma state characterized by a distinct plasma impedance in an ALE process. The process 602 initiates at step 608 where plasma impedances are computed utilizing the chamber plasma digital twin 152. Subsequently, in step 610, resonating frequencies corresponding to various plasma states are ascertained based on the RF digital twin 146. Thereafter, in step 612, the RF digital twin 146 is updated to reflect the determined resonating frequencies.

FIG. 6B sets forth a flowchart delineating the steps for establishing the set point of the valve in accordance with the gas digital twin 148. The terms: “the set point for the actuator of the valve” and “the set point of the valve” have been used in this disclosure without difference. The process 604 begins at step 614 by calculating the chamber pressure using the gas digital twin 148, with this calculation premised upon an initial set point for the valve 126. Step 616 involves ascertaining the set point to achieve the desired chamber pressure. Following this, the gas digital twin 148 is revised to include the updated set point.

FIG. 6C illustrates a flowchart detailing the procedure for defining set points for a heater and a chiller. Process 606 commences with step 620, wherein the substrate surface temperature is computed by the temperature digital twin 150, using preliminary set points for the heater 128 and the chiller 130. Step 622 involves the determination of the set points for maintaining the substrate temperature within the desired range using the temperature digital twin 150. Finally, at step 624, the temperature digital twin 150 is amended to include the optimized set points. It has been pointed out previously that the temperature digital twin 150 alone may not be sufficient in determining the surface temperature of the substrate. The effects of fluxes like ion flux need to be integrated, which requires joint work from the temperature digital twin 150 and the surface flux digital twin 153.

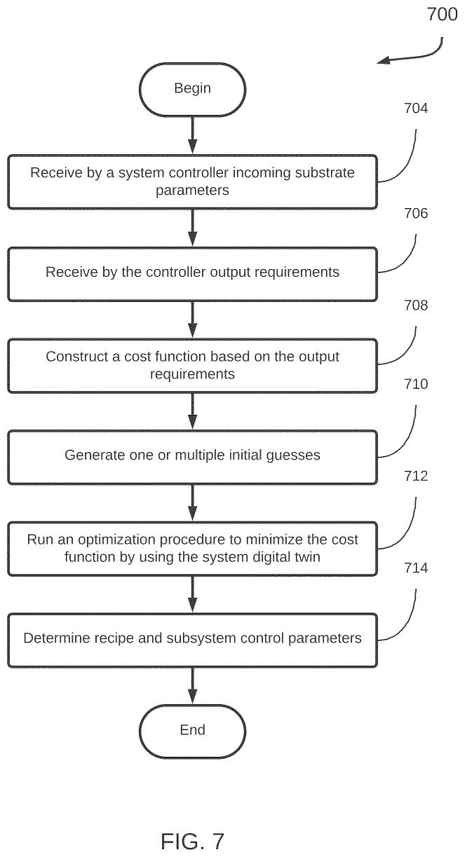

FIG. 7 presents a flowchart outlining a method for formulating process recipe parameters and subsystem control parameters utilizing the system digital twin 140. The process 700 commences at step 704 when the system controller 132 acquires incoming substrate parameters, as detailed in Table 1. In step 706, the system controller 132 procures the output parameters for the structures to undergo etching, constructing a cost function based upon the output requirements in step 708, typically formulated as a least squares cost function pertaining to each output parameter of the structure post the ALE processing, the cost function can be defined as:

$$c = {\sum }_{i = 1}^{N} {{w}_{i} ( {p}_{i} - {p}_{itarget} )}^{2} , \qquad [ 1 ]$$

where c is the cost, wᵢ is the weight, and pᵢ is a normalized output parameter like critical dimension at a selected vertical coordinate, p_{itarget} is the normalized target value of the output parameter, and N is serial number of the parameter. If multiple structures are evaluated, the cost function can be further expressed as:

$$C = {\sum }_{j = 1}^{M} {W}_{j} {c}_{j} , \qquad [ 2 ]$$

where C is the accumulated cost across multiple structures, W is the weight, and c is the cost for one structure. The method can take several or many structures across a substrate like a 300 mm wafer. The method can further take different structures or different parts of the structure to quantify various loading effects. Therefore, the optimization process 700 can be employed to optimize a single structure or multiple structures concurrently. In some implementations, if loading effects need to be modeled accurately, Equation [2] may include further additional terms which reflect correlations.

Proceeding to step 710, initial guesses for the process recipe parameters and subsystem control parameters are devised, providing a basis to execute an optimization algorithm in step 712. This optimization, aimed at minimizing the cost function, is performed in accordance with the ALE digital twin 300 or more efficiently the ALE neural network 414. The optimization can be carried out by many algorithms as known in the art, such as, for example, the stochastic gradient descent (SGD) method. At the conclusion of this process, at step 714, the process recipe parameters and subsystem control parameters are established.

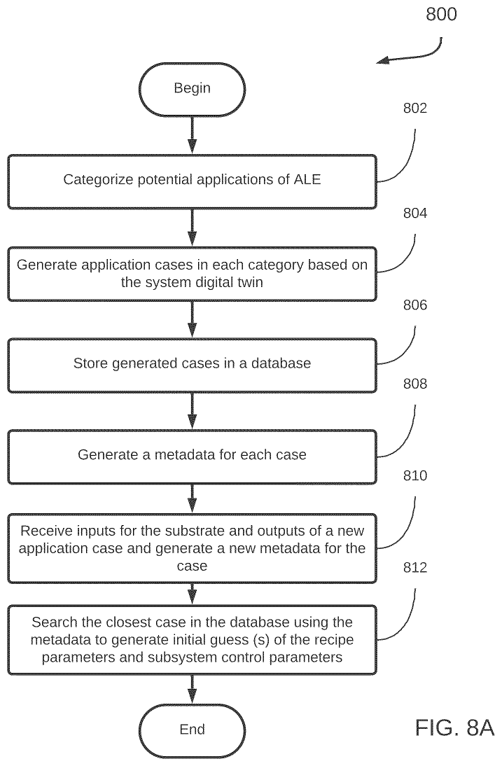

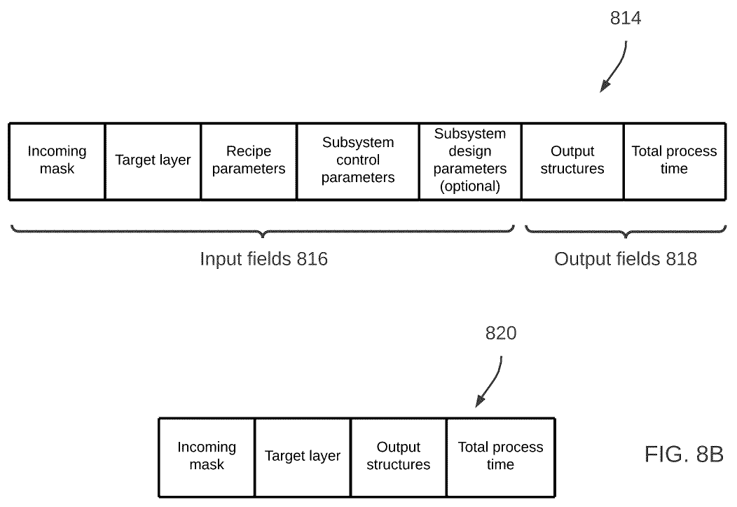

FIG. 8A sets forth a flowchart detailing a process for formulating an initial guess of the recipe and system control parameters. Process 800 initiates with step 802, wherein potential application cases of the ALE utilizing an ALE process system are systematically categorized. In one implementation, the applications cases are based on a single ALE process system. In another implementation, the application cases maybe based on several different designs of the process systems. For the lateral situation, selected design parameters will be included in the input parameters. The ALE process, for instance, may be utilized for the etching of high aspect ratio structures, patterning transfer layers, and metal interconnect layers. In step 804, the system controller 132 fabricates many cases for each defined category, utilizing the ALE digital twin 300 or the ALE neural network 414. Employing the computation-efficient ALE neural network 414 can significantly reduce the computational burden for each case. These computations, executable in the background over time, facilitate the generation of an extensive array of test cases. Subsequently, the synthesized cases are archived in a database in step 806. It is imperative that this compilation encompasses a comprehensive spectrum of variations for recipe and subsystem control parameters, thereby spanning a vast range of potential outputs. Step 808 involves the creation of metadata for each case, where the metadata's structure is specifically crafted to encapsulate the interrelations between input and output parameters and is readily accessible for search queries.

In some implementations, the application cases may be established by a centralized server and may be stored in a centralized storage media for a fleet of chambers instead of the system controller for a single process system.

In one embodiment, the metadata fields are meticulously structured to correspond with both input and output parameters, with each field assigned a unique code linked to discrete input parameter values. Output parameters are likewise encoded for association with metadata fields.

An exemplary metadata structure is illustrated in FIG. 8B, denoted as 814. The exemplary metadata includes input fields 816 and output fields 818. The input fields 816 further include but are not limited to subfields for incoming mask, target layer to be etched, recipe parameters, subsystem control parameters, and subsystem design parameters (optional). Each subfield can be further divided into more detailed descriptions of the parameters of the subfield. For example, the incoming mask should include every layer if the mask is multi-layer stack, its material identity/properties, thickness, critical dimension, profiles, etc. Each parameter should be encoded based on a commonly accepted protocol.

The output fields 818 further comprise parameters describing the output structures post ALE processing, as listed exemplarily in Table 1. The output structures may further include parameters describing post ALE mask thickness and profiles, which indicate selectivity of the ALE process.

The output field also includes a total process time for the ALE process, which is an important indicator for the cost of the ALE process. Similarly, the details of each subfield in the output field 818 should be encoded according to a common protocol.

Upon reception of a new application case characterized by specific incoming substrate and output parameters in step 810, these parameters are encoded to produce corresponding metadata according to the same protocol as described exemplarily in FIG. 8B. This newly generated metadata is then utilized to locate the closest match, or exact matches, within the database during step 812. The subfield describing recipe parameters and subsystem control parameters may leave as blank for the new application cases. FIG. 8B showcases further a simplified metadata structure, denoted as 820. For a new case, it attempts to match the essential fields related to inputs and outputs of the structure while the process recipe parameters and the subsystem control parameters are results of matched query. The total process time is an important field to be matched. An error function can be defined to quantify the goodness of the matching. The error function can be constructed by measure deviation of each input and output parameter using a lest square formulation with assigned weight for each term.

Following this retrieval, an initial conjecture for the new application case's recipe parameters and subsystem control parameters is formulated in step 812. If there is an exact match within a predefined boundary defined by the error function, no further optimization is required.

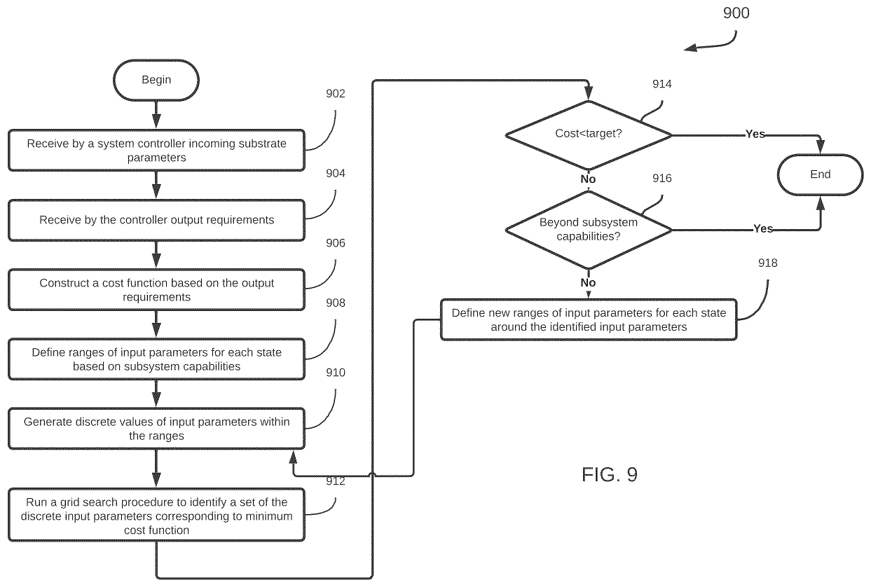

FIG. 9 illustrates a flowchart depicting the procedure for generating recipe and subsystem control parameters through a multi-stage grid search methodology. Process 900 begins with step 902, where the system controller 132 receives incoming substrate parameters, as depicted in Table 1. In step 904, the system controller 132 is provided with output requirements for the structures to be etched, and a cost function is established based on these requirements at step 906, typically formulated as a least squares error function pertaining to each output parameter with assigned weights. Step 908 involves delineating the permissible ranges for input parameters based on subsystem capabilities; these ranges are generally pre-established and stored within the system controller's 132 storage media. Step 910 entails generating a series of discrete values for input parameters within these specified ranges. For instance, S1 and S2 represent critical states in the ALE process. The RF power and its on-state duration for the states can be treated as variables, assigned with discrete values. To thoroughly explore the input parameter space, the system controller 132 may allocate four discrete values each for power and duration, yielding 16 variations per state and 256 combinations for S1 and S2 alone. The quantity of variations increases significantly when additional states and parameters are considered. It is therefore required to create a balance between the scope of variations and the computational resources required. A learning strategy deployed includes progressively refining the search space to pinpoint the global minimum and prevent confinement within local minima. At step 912, the system controller 132 runs a grid search algorithm to evaluate the cost function across the space of the discrete input parameters. Through an extensive search, the system controller 132 identifies the optimal parameters corresponding to the minimal cost value. The ALE neural network 414 is computationally efficient and makes the grid search algorithm feasible within a reasonable amount of computing resources.

Although training of the neural network is time-consuming, the inference operations are relatively fast and with lower cost. Upon determining the discrete input parameters yielding the minimal cost, the system controller 132 conducts a comparison with the predetermined target cost value at step 914. If the calculated cost falls below the target, process 900 concludes. Conversely, if the cost exceeds the target, and the identified input parameters are at the limits of the subsystem's capabilities as recognized at step 916, the process also concludes. If the cost is above the target but the parameters are within the capabilities of the subsystems, step 918 is undertaken to refine the search range. The process 900 goes back to step 910 to continue to optimize the cost function.

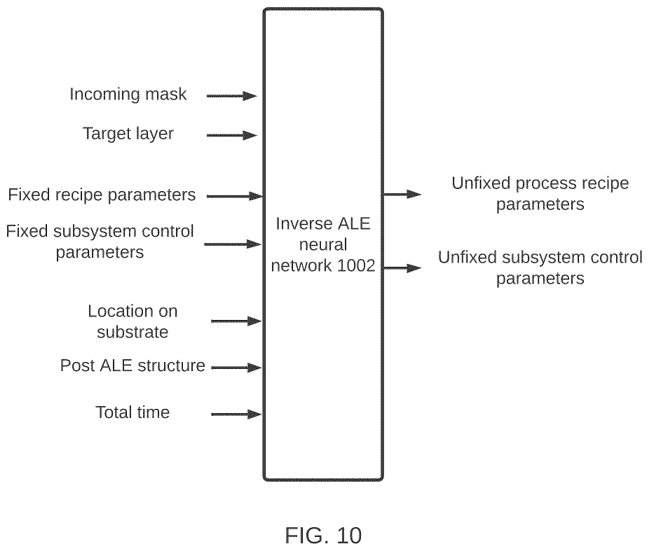

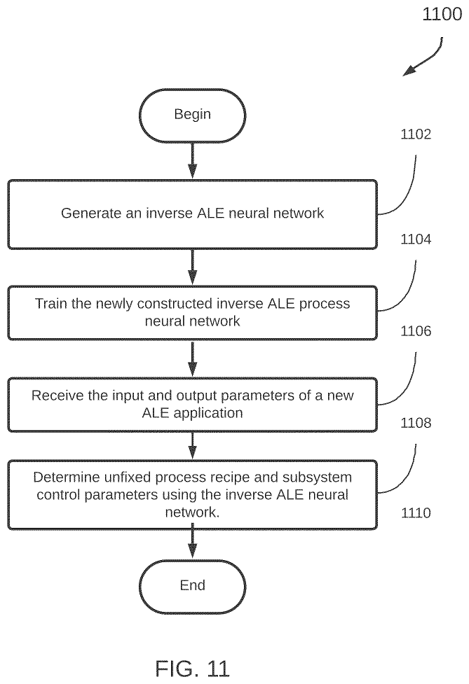

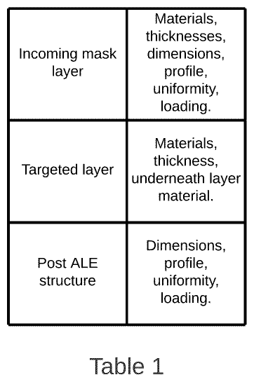

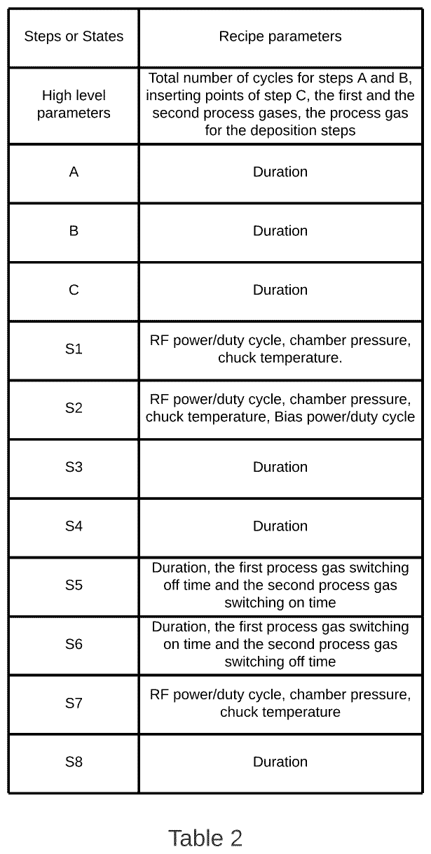

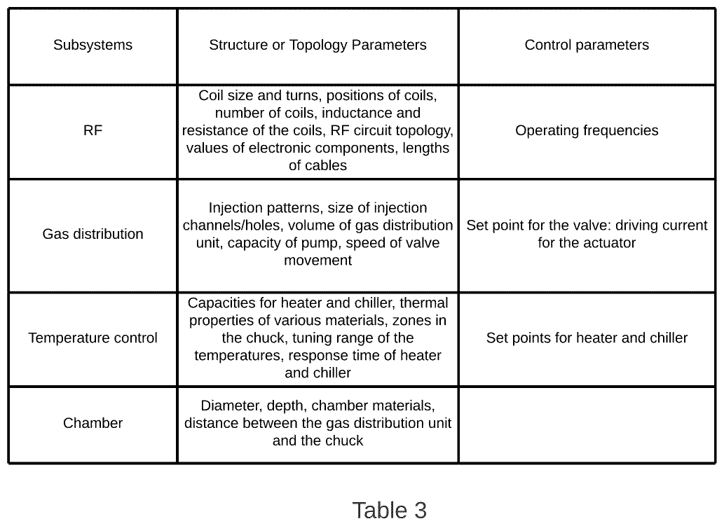

FIG. 10 showcases a schematic representation of an inverse ALE neural network 1002 for the ALE process system. The inverse ALE neural network 1002 takes incoming substrate parameters and the output structure parameters as its inputs. The parameters for the process recipe are divided into a fixed subgroup and an unfixed subgroup. The fixed subgroup is also taken as the inputs for the neural network 1002. Similarly, the subsystem control parameters are also divided into fixed and unfixed subgroups. The unfixed groups include selected process recipe parameters and selected subsystem control parameters to be determined by the inverse ALE neural network 1002. The inputs of 1002 further include the location of the structure on the substrate as well as the total process time. The outputs of the neural network 1002 include the unfixed process recipe parameters and the unfixed system control parameters. The inverse ALE neural network 1002 will need to be trained based on the data generated by the ALE digital twin 300 or its neural network implementation 414.

FIG. 11 presents a flowchart delineating the method for ascertaining unfixed recipe parameters and unfixed subsystem control parameters, employing the inverse ALE neural network 1002 tailored to the ALE process system. Process 1100 commences with step 1102, where the inverse ALE neural network 1002 is formulated. The inverse ALE neural network 1002 is designed such that the output structure parameters, as depicted in Table 1, and the total process time serve as its inputs. The inputs also include the parameters for the incoming mask and targeted layers as shown in Table 1. Concurrently, selected process recipe parameters as listed in Table 1 are configured as the network's outputs. It is critical to recognize the flexibility in assigning these parameters, which may vary based on specific applications. In certain instances, RF powers may be selected as outputs, whereas in other scenarios, they may be used as inputs or maintained constant. The input parameters may also include fixed system control parameters. For example, if gas and temperature subsystem control parameters are fixed, the RF subsystem control parameters like operating frequencies can be the unfixed ones as one of the outputs of the inverse neural network 1002. All these permutations are encompassed within the scope of the inventive concept at hand.

Reverting to FIG. 11, the inverse ALE neural network 1002 undergoes a training phase at step 1104, utilizing the ALE digital twin 300. Given that the neural network implementation of the digital twin 140 facilitates computational efficiency, it enables the generation of a voluminous dataset suitable for training an expansive neural network.

Step 1106 involves the system controller 132 receiving a new application case, complete with incoming substrate parameters and defined output requirements. The trained inverse neural network 1002 is then employed in step 1108 to derive the unfixed process recipe parameters and subsystem control parameters.

The ALE process system has been used throughout this disclosure to elaborate on the inventive concept. This approach should be considered exemplary and not limit the scope of the inventive concept. The invention should cover any type of etching and deposition process systems involving plasma process chambers. Additionally, the inventive concept can be extended to thermal process systems wherein the RF subsystems and plasma are not used. For such applications, the system digital twin can still be constructed similarly without the presence of the RF and chamber plasma digital twins.

1. An ALE process system, comprising:
a plasma process chamber designed for a vacuum environment;
an RF subsystem configured to deliver RF power to a plasma source and to provide a bias to a chuck that supports a substrate;
a gas distribution subsystem designed to supply a first process gas for a surface modification step and a second process gas for a sputtering step of an ALE process, wherein the gas distribution subsystem further comprises a pump and a valve to evacuate unconsumed gases and reaction byproducts from the plasma process chamber;
a temperature control subsystem arranged to maintain a prescribed operating temperature for the substrate, further comprising a heater and a chiller; and
a system controller designed to determine selected process recipe parameters and selected subsystem control parameters, wherein these determinations are based on a system digital twin, wherein the system controller takes into account a first data set characterizing an incoming substrate and a second data set defining desired output specifications of the substrate, wherein the system digital twin further includes:
a first digital twin for the RF subsystem;
a second digital twin for the gas distribution subsystem;
a third digital twin for the temperature control subsystem;
a fourth digital twin for the plasma process chamber, which receives inputs from the first, second, and third digital twins and generates 2D or 3D distribution maps of electrons, ions, and neutrals within the plasma process chamber;
a fifth digital twin for determining the ion and neutral fluxes at the substrate's surface and predicting jointly with the third digital twin the surface temperature of the substrate;
a sixth digital twin for the ALE process, accepting as inputs the ion flux, neutral flux, and substrate surface temperature to simulate and provide structure progressions of the substrate undergoing the ALE process.

2. The process system of claim 1, wherein the first digital twin comprises a model that includes a SPICE model of the RF subsystem.

3. The process system of claim 1, wherein the first, the second, the third, the fourth, the fifth, and the sixth digital twins further comprise trained neural networks.

4. The process system of claim 3, wherein the neural networks are trained using synthetic data from simulations conducted based on the digital twins.

5. The process system of claim 4, wherein measured data is utilized to enhance the training, wherein the measured data is assigned greater weight during the training.

6. The process system of claim 1, wherein the generation of selected process recipe parameters and selected subsystem control parameters further employes an optimization procedure executed by the system controller to minimize a predefined cost function, wherein the cost function can be designed for a single structure or a group of structures.

7. The process system of claim 6, wherein the optimization procedure further includes a grid search method or a multi-stage grid search method, wherein the grid can be refined progressively.

8. The process system of claim 6, wherein the system controller additionally includes a database comprising a plurality of simulated application cases, wherein the simulated application cases are accumulated in background over time.

9. The process system of claim 8, wherein each application case is linked with a metadata that includes parameters of the incoming substrate and the desired output specification of the substrate.

10. The process system of claim 9, wherein an initial guess for the optimization procedure for a new application case is ascertained by querying the database using the metadata to identify the most analogous cases contained within.

11. The process system of claim 1, wherein the generation of selected process recipe parameters and selected subsystem control parameters further includes employing an inverse ALE neural network, wherein the inverse ALE neural network is configured with incoming substrate parameters and post ALE structure parameters as its inputs and selected process recipe and selected subsystem control parameters as its outputs.

12. The process system of claim 1, wherein resonator frequencies of the RF subsystems are determined by the system controller, which calculates plasma impedance based on the fourth digital twin.

13. The process system of claim 1, wherein a set point for an actuator of the valve in the second digital twin is determined by the system controller through calculations of chamber pressure derived from the second digital twin.

14. A method for formulating a process recipe for an ALE process in a plasma process chamber, the method comprising:
a) generating a suite of digital twins, including:
a first digital twin for an RF subsystem, wherein the RF subsystem is configured to deliver RF power to a plasma source and to provide a bias to a chuck that supports a substrate;
a second digital twin for the gas distribution subsystem, wherein the gas distribution subsystem is designed to supply a first process gas for a surface modification step and a second process gas for a sputtering step of an ALE process, wherein the gas distribution subsystem further comprises a pump and a valve to evacuate unconsumed gases and reaction byproducts from the plasma process chamber;
a third digital twin for the temperature control subsystem, wherein the temperature control subsystem is arranged to maintain a prescribed operating temperature for the substrate;
a fourth digital twin for the plasma process chamber, which receives inputs from the first, second, and third digital twins to generate 2D or 3D distribution maps for electrons, ions, and neutrals within the plasma process chamber;
a fifth digital twin for determining ion and neutral fluxes at the substrate surface, as well as the substrate's surface temperature, wherein the temperature is determined based additionally on the third digital twin;
a sixth digital twin for the ALE process, which takes ion flux, neutral flux, and surface temperature to model the progressive structural changes of the substrate over time;
b) receiving at a system controller a first data set describing an incoming substrate including parameters describing the mask layer and targeted layer for the ALE processing, and a second data set outlining desired output structure parameters; and
c) leveraging the suite of digital twins to generate selected process recipe parameters and selected subsystem control parameters.

15. The method of claim 14, wherein at least one digital twin is a trained neural network.

16. The method of claim 15, further including a step of training the neural networks using synthetic data from simulations based on the digital twins.

17. The method of claim 16, further comprising enhancing the training by employing measured data and assigning greater weight to the measured data for the training.

18. The method of claim 14, wherein the step c) further comprises a step of executing an optimization procedure by the system controller to minimize a predefined cost function, wherein the cost function can be designed for a single structure or a group of structures.

19. The method of claim 18, wherein the optimization procedure further includes a grid search or a multi-stage grid search method.

20. The method of claim 14, wherein the step c) further includes utilizing an inverse ALE neural network, wherein the inverse ALE neural network receives incoming substrate parameters and post ALE structure parameters as inputs and provides selected process recipe and subsystem control parameters as outputs.
